(19) United States
(12) Patent Application Publication
(10) Pub. No.: US 2026/0013365 A1
(43) Pub. Date: Jan. 8, 2026

(54) DISPLAY DEVICE AND ELECTRONIC DEVICE INCLUDING THE SAME

(71) Applicant: Samsung Display Co., LTD., Yongin-si (KR)

(72) Inventors: SUNJIN JOO, Yongin-si (KR); SE HEE KIM, Yongin-si (KR); NARI HEO, Yongin-si (KR); SANG MIN HONG, Yongin-si (KR)

(21) Appl. No.: 19/050,263

(22) Filed: Feb. 11, 2025

(30) Foreign Application Priority Data
Jul. 4, 2024 (KR) 10-2024-0088266

(51) Int. Cl. H10K 59/00; H10K 59/35; H10K 59/80

(52) U.S. Cl. CPC H10K 59/771; H10K 59/353; H10K 59/8792

(57) ABSTRACT

A display device includes light-emitting areas respectively emitting red light, green light and blue light, a non-light emitting area which is between the light-emitting areas. and in each of the light-emitting areas a hole transport layer, a light-emitting layer on the hole transport layer, an electron transport layer on the light-emitting layer, an electron injection layer which is on the electron transport layer and has a thickness, and among the light-emitting areas, the thickness of the electron injection layer in the light-emitting area which emits the red light being greater than the thickness of the electron injection layer in the light-emitting area which emits the green light and being greater than the thickness of the electron injection layer in the light-emitting area which emits the blue light.

This application claims priority to Korean Patent Application No. 10-2024-0088266 filed on Jul. 4, 2024, and all the benefits accruing therefrom under 35 U.S.C. § 119, the entire contents of which are hereby incorporated by reference.

### BACKGROUND

### 1. Field

Embodiments provide generally to a display device. More particularly, embodiments relate to a display device which provides visual information.

### 2. Description of the Related Art

As information technology develops, the importance of display devices, which are communication media between users and information, is being highlighted. Accordingly, the use of display devices such as a liquid crystal display device, an organic light-emitting display device, a plasma display device, and the like is increasing.

### SUMMARY

As a display device includes conductive lines, signal lines, electrodes, etc. including metal, external light incident on the display device may be reflected from these lines and electrodes. To reduce or effectively prevent reflection of external light by these elements, the display device generally includes a polarizer. However, although the polarizer may prevent reflection of external light, the light efficiency of the display device may be reduced due to the polarizer.

Embodiments provide a display device having improved quality.

Embodiments provide an electronic device including the display device.

A display device according to embodiments of the present disclosure includes a substrate including a first light-emitting area, a second light-emitting area, a third light-emitting area, and a non-light emitting area between the first, second, and third light-emitting areas, a hole transport region disposed on the substrate, a first light-emitting layer disposed in the first light-emitting area on the hole transport region and including a light-emitting material which emits light of a first color, a second light-emitting layer disposed in the second light-emitting area on the hole transport region and including a light-emitting material which emits light of a second color different from the first color, a third light-emitting layer disposed in the third light-emitting area on the hole transport region and including a light-emitting material which emits light of a third color different from the first and second colors, an electron transport layer disposed on the first, second, and third light-emitting layers, a first electron injection layer disposed in the first light-emitting area on the electron transport layer and having a first thickness, a second electron injection layer disposed in the second light-emitting area on the electron transport layer and having a second thickness thinner (e.g., less) than the first thickness, and a third electron injection layer disposed in the third light-emitting area on the electron transport layer and having a third thickness thinner than the first thickness.

In an embodiment, the first color may be red, the second color may be green, and the third color may be blue.

In an embodiment, the second thickness may be equal to the third thickness.

In an embodiment, the first, second, and third electron injection layers may be disposed to be spaced apart from each other.

In an embodiment, the first, second, and third electron injection layers may include a lanthanum-based metal material.

In an embodiment, the first, second, and third electron injection layers may include ytterbium (Yb).

In an embodiment, the first, second, and third electron injection layers may simultaneously include a metal halide material and a lanthanum-based metal material.

In an embodiment, the lanthanum-based metal material may include ytterbium (Yb).

In an embodiment, each of the first, second, and third thicknesses may range from about 7.5 angstroms (Å) to about 18.5 angstroms (Å).

In an embodiment, the electron transport layer may be disposed as a common layer in the first, second, and third light-emitting areas and the non-light emitting area.

In an embodiment, the hole transport region may include a hole injection layer disposed on the substrate and a hole transport layer disposed on the hole injection layer.

In an embodiment, the hole transport region may be disposed as a common layer in the first, second, and third light-emitting areas and the non-light emitting area.

In an embodiment, the display device may further include an encapsulation layer disposed on the first, second, and third electron injection layers and including at least one organic layer and at least one inorganic layer, a light blocking layer disposed on the encapsulation layer and overlapping the non-light emitting area, and first, second, and third color filters disposed in the first, second, and third-emitting areas on the light blocking layer, respectively.

In an embodiment, the display device may further include an overcoat layer disposed on the first, second, and third color filters.

In an embodiment, the display device may further include an encapsulation layer disposed on the first, second, and third electron injection layers and including at least one organic layer and at least one inorganic layer, a light blocking layer disposed on the encapsulation layer and overlapping the non-light emitting area, and a reflection control layer disposed on the light blocking layer and including an inorganic material or an organic material, each of the inorganic material and the organic material containing dye, pigment, and combinations thereof.

A display device according to embodiments of the present disclosure includes a substrate including a first light-emitting area, a second light-emitting area, a third light-emitting area, and a non-light emitting area between the first, second, and third light-emitting areas, a hole transport region disposed on the substrate, a first light-emitting layer disposed in the first light-emitting area on the hole transport region and including a light-emitting material which emits light of red, a second light-emitting layer disposed in the second light-emitting area on the hole transport region and including a light-emitting material which emits light of green, a third light-emitting layer disposed in the third light-emitting area on the hole transport region and including a light-emitting material which emits light of blue, an electron transport layer disposed on the first, second, and third light-emitting layers, a first electron injection layer disposed in the first light-emitting area on the electron transport layer and having a first thickness, a second electron injection layer disposed in the second light-emitting area on the electron transport layer and having a second thickness thinner than the first thickness, a third electron injection layer disposed in the third light-emitting area on the electron transport layer and having a third thickness thinner than the first thickness, a light blocking layer disposed on the first, second, and third electron injection layers and defining first, second, and third openings overlapping the first, second, and third light-emitting areas, respectively, and first, second, and third color filters disposed to fill the first, second, and third openings, respectively.

In an embodiment, the first, second, and third electron injection layers may be disposed to be spaced apart from each other.

In an embodiment, the first, second, and third electron injection layers may include a lanthanum-based metal material.

In an embodiment, the first, second, and third electron injection layers may include ytterbium (Yb).

In an embodiment, each of the first, second, and third thicknesses may range from about 7.5 angstroms (Å) to about 18.5 angstroms (Å).

An electronic device according to embodiments of the present disclosure includes a display device and a processor which controls the display device, the display device includes a substrate including a first light-emitting area, a second light-emitting area, a third light-emitting area, and a non-light emitting area between the first, second, and third light-emitting areas, a hole transport region disposed on the substrate, a first light-emitting layer disposed in the first light-emitting area on the hole transport region and including a light-emitting material which emits light of a first color, a second light-emitting layer disposed in the second light-emitting area on the hole transport region and including a light-emitting material which emits light of a second color different from the first color, a third light-emitting layer disposed in the third light-emitting area on the hole transport region and including a light-emitting material which emits light of a third color different from the first and second colors, an electron transport layer disposed on the first, second, and third light-emitting layers, a first electron injection layer disposed in the first light-emitting area on the electron transport layer and having a first thickness, a second electron injection layer disposed in the second light-emitting area on the electron transport layer and having a second thickness thinner than the first thickness, and a third electron injection layer disposed in the third light-emitting area on the electron transport layer and having a third thickness thinner than the first thickness.

In the display device according to embodiments of the present disclosure, by making a first thickness of a first electron injection layer disposed in a first light-emitting area which emits light of red thicker (e.g., greater) than each of a second thickness of a second electron injection layer disposed in a second light-emitting area which emits light of green and a third thickness of a third electron injection layer disposed in a third light-emitting area which emits light of blue, red luminance ratio when a viewing angle is high may be relatively large. Accordingly, when the viewing angle is high, the bluish display of the image on the display device may be minimized or reduced.

### BRIEF DESCRIPTION OF THE DRAWINGS

Illustrative, non-limiting embodiments will be more clearly understood from the following detailed description in conjunction with the accompanying drawings.

FIG. 1 is a plan view showing a display device according to an embodiment of the present disclosure.

FIG. 2 is a cross-sectional view taken along line I-I′ of FIG. 1.

FIG. 3 is a cross-sectional view for explaining a first light-emitting element of FIG. 2.

FIG. 4 is a cross-sectional view for explaining a second light-emitting element of FIG. 2.

FIG. 5 is a cross-sectional view for explaining a third light-emitting element of FIG. 2.

FIGS. 6, 7, 8, 9, 10, 11, and 12 are cross-sectional views for explaining a method for manufacturing (or providing) the display device of FIG. 2.

FIG. 13 is a cross-sectional view showing a display device according to an embodiment of the present disclosure.

FIG. 14 is a block diagram showing an electronic device according to embodiments of the present disclosure.

FIG. 15 are schematic diagrams showing an electronic device according to various embodiments.

### DETAILED DESCRIPTION

Hereinafter, a display device DD and an electronic device 10 including the same according to embodiments of the present disclosure will be explained in detail with reference to the accompanying drawings. The same reference numerals are used for the same components in the drawings, and redundant descriptions of the same components will be omitted.

It will be understood that when an element is referred to as being related to another element such as being “on” another element, it can be directly on the other element or intervening elements may be present therebetween. In contrast, when an element is referred to as being related to another element such as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

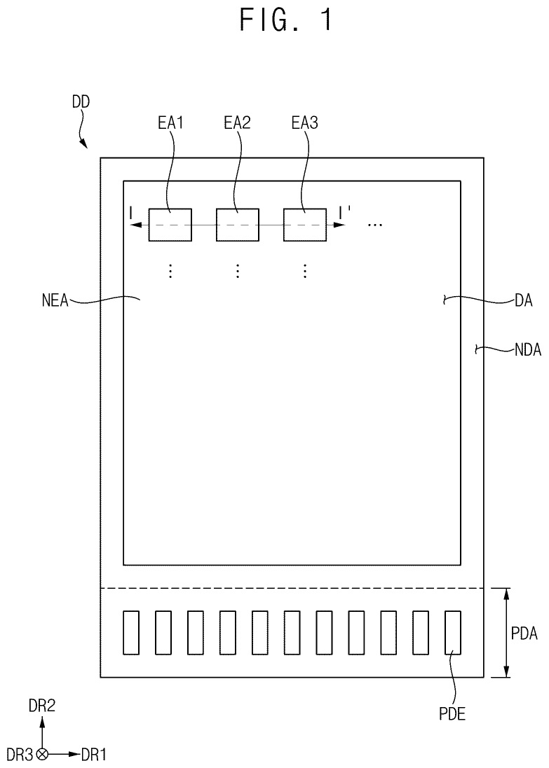

FIG. 1 is a plan view showing a display device DD according to an embodiment of the present disclosure.

Referring to FIG. 1, a display device DD according to an embodiment of the present disclosure may include a display area DA and a non-display area NDA. The display area DA may be an area (e.g., a planar area) at which an image is displayed such as by generating light or adjusting the transmittance of light provided from an external light source. The non-display area NDA may be an area at which an image is not displayed. The non-display area NDA is adjacent to the display area DA, and may be located around the display area DA. For example, the non-display area NDA may entirely surround the display area DA.

The display area DA may include a plurality of light-emitting areas and a non-light emitting area NEA which is between the light-emitting areas. The light-emitting areas may be arranged in a matrix form along a first direction DR1 and a second direction DR2 which intersects the first direction DR1. For example, the light-emitting areas may include a first light-emitting area EA1, a second light-emitting area EA2, and a third light-emitting area EA3.

Each of the first light-emitting area EA1, the second light-emitting area EA2, and the third light-emitting area EA3 may mean an area where light emitted from a light-emitting element is emitted to an outside of the display device DD. For example, the first light-emitting area EA1 may emit light of a first color, the second light-emitting area EA2 may emit light of a second color, and the third light-emitting area EA3 may emit light of a third color. In an embodiment, the first color may be red, the second color may be green, and the third color may be blue. However, embodiments of the present disclosure are not necessarily limited thereto. For example, the first, second, and third light-emitting areas EA1, EA2, and EA3 may be combined to emit yellow, cyan, and magenta lights.

The first, second, and third light-emitting areas EA1, EA2, and EA3 may emit light of four or more colors. For example, the first, second, and third light-emitting areas EA1, EA2, and EA3 may be combined to emit at least one of yellow, cyan, and magenta lights in addition to red, green, and blue lights. In addition, the first, second, and third light-emitting areas EA1, EA2, and EA3 may be combined to emit more white light.

Each of the first light-emitting area EA1, the second light-emitting area EA2, and the third light-emitting area EA3 may have a triangular planar shape, a rectangular planar shape, a circular planar shape, an oval planar shape, or the like. In an embodiment, each of the first light-emitting area EA1, the second light-emitting area EA2, and the third light-emitting area EA3 may have a rectangular planar shape. However, the embodiments of the present disclosure are not necessarily limited, and each of the first light-emitting area EA1, the second light-emitting area EA2, and the third light-emitting area EA3 may have a different planar shape.

The non-display area NDA may include a pad area PDA. The pad area PDA may be located extending away from one side of the display area DA. For example, the pad area PDA may have a shape extending in the first direction DR1, where the shape is defined by a major dimension in the first direction DR1.

A plurality of lines (e.g., signal lines, conductive lines, etc.) may be disposed in the non-display area NDA, and a pad electrode PDE provided in plural including a plurality of pad electrodes PDE may be disposed in the pad area PDA. The lines (not shown) may electrically connect the pad electrodes PDE and the light-emitting areas to each other. For example, the lines may include data signal lines, scan signal lines, light-emitting control signal lines, power voltage lines, and the like. The lines may have portions in the display area DA and in the non-display area NDA to connect a pad electrode PDE to a light-emitting area, without being limited thereto.

The pad electrodes PDE may be disposed to be spaced apart from each other in the first direction DR1. For example, each of the pad electrodes PDE may include metal, alloy, metal nitride, conductive metal oxide, transparent conductive material, and the like. These can be used alone or in combination with each other.

In this specification, a plane may be defined by the first direction DR1 and the second direction DR2 which intersects the first direction DR1. For example, the first direction DR1 and the second direction DR2 may be perpendicular to each other. In addition, the third direction DR3 may be perpendicular to the plane. A thickness of the display device DD and various components or layers thereof may be defined along the third direction DR3 (e.g., a thickness direction).

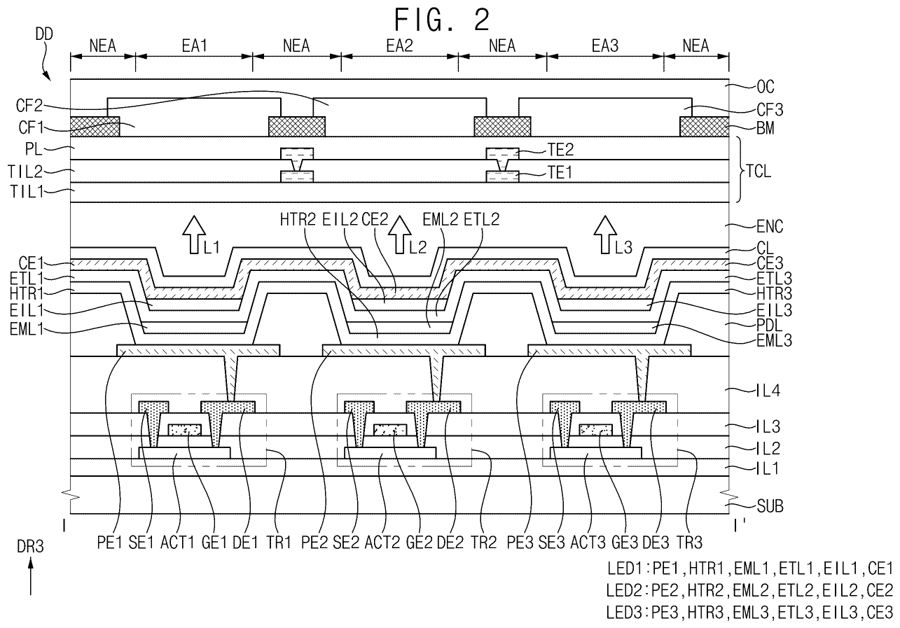

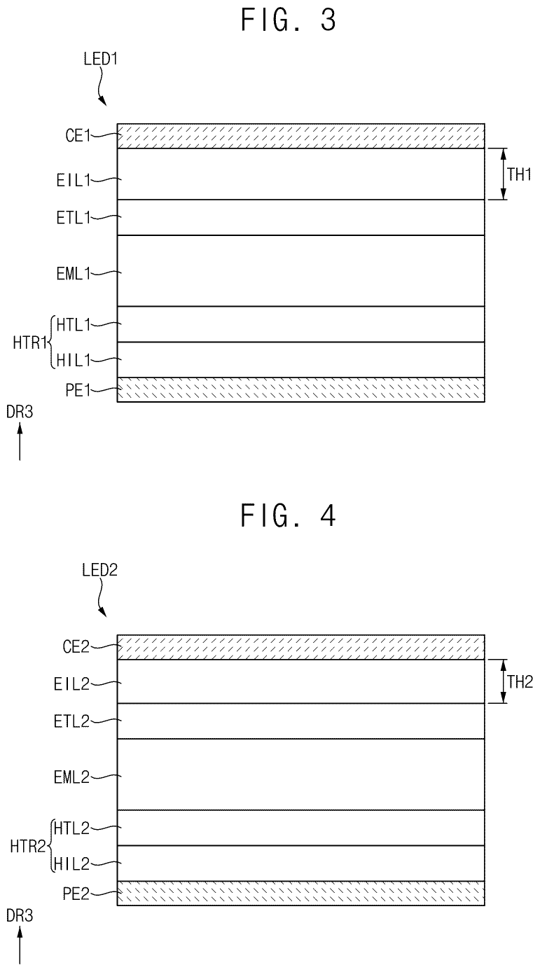

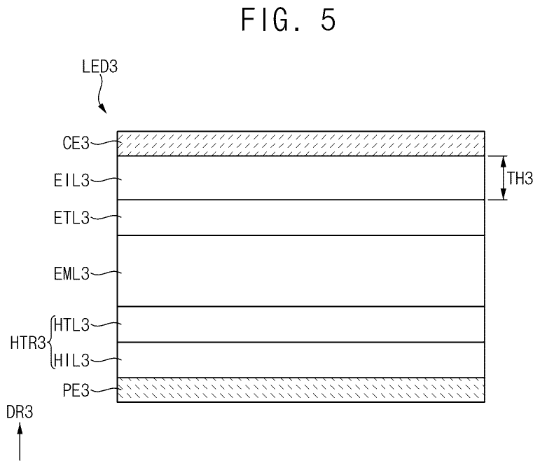

FIG. 2 is a cross-sectional view taken along line I-I′ of FIG. 1. FIG. 3 is a cross-sectional view for explaining a first light-emitting element LED1 of FIG. 2. FIG. 4 is a cross-sectional view for explaining a second light-emitting element LED2 of FIG. 2. FIG. 5 is a cross-sectional view for explaining a third light-emitting element LED3 of FIG. 2.

Referring to FIGS. 2, 3, 4, and 5, the display device DD may include a substrate SUB, a transistor provided in plural such as first, second and third transistors TR1, TR2, and TR3, an insulating layer provided in plural such as first, second, third and fourth insulating layers IL1, IL2, IL3, and IL4, a pixel defining layer PDL, a light-emitting element provided in plural such as first, second and third light-emitting elements LED1, LED2 and LED3, a capping layer CL, an encapsulation layer ENC, a touch sensing layer TCL, a light blocking layer BM, a color filter provided in plural such as first, second, and third color filters CF1, CF2, and CF3, and an overcoat layer OC.

Here, the first transistor TR1 may include a first active pattern ACT1, a first gate electrode GE1, a first source electrode SE1 and a first drain electrode DE1, the second transistor TR2 may include a second active pattern ACT2, a second gate electrode GE2, a second source electrode SE2 and a second drain electrode DE2, and the third transistor TR3 may include a third active pattern ACT3, a third gate electrode GE3, a third source electrode SE3 and a third drain electrode DE3.

In addition, the first light-emitting element LED1 may include a first pixel electrode PE1, a first hole transport region HTR1, a first light-emitting layer EML1, a first electron transport layer ETL1, and a first electron injection layer EIL1 and a first common electrode CE1, the second light-emitting element LED2 may include a second pixel electrode PE2, a second hole transport region HTR2, a second light-emitting layer EML2, a second electron transport layer ETL2, a second electron injection layer EIL2 and a second common electrode CE2, and the third light-emitting element LED3 may include a third pixel electrode PE3, a third hole transport region HTR3, a third light-emitting layer EML3, a third electron transport layer ETL3, a third electron injection layer EIL3 and a third common electrode CE3.

As described above, the display device DD may include the display area DA and the non-display area NDA. As the display device DD includes the display area DA and the non-display area NDA, a component included in the display device DD (e.g., the substrate SUB) may also include a display area DA and a non-display area NDA corresponding to those described for the display device DD.

The substrate SUB may include a transparent material or an opaque material. The substrate SUB may be made of (or include) a transparent resin substrate. Examples of the transparent resin substrate include a polyimide substrate. In this case, the polyimide substrate may include a first organic layer, a first barrier layer, a second organic layer, and the like. Alternatively, the substrate SUB may include a quartz substrate, synthetic quartz substrate, calcium fluoride substrate, F-doped quartz substrate, a soda-lime glass substrate, a non-alkali glass substrate, and the like. These can be used alone or in combination with each other.

The first insulating layer IL1 may be disposed on the substrate SUB. The first insulating layer IL1 can prevent metal atoms or impurities from diffusing from the substrate SUB to the first, second, and third transistors TR1, TR2, and TR3. In addition, the first insulating layer IL1 may improve the flatness of the surface of the substrate SUB when the surface of the substrate SUB is not uniform. For example, the first insulating layer IL1 may include an inorganic material such as silicon oxide (SiOₓ), silicon nitride (SiNₓ), silicon oxynitride (SiOₓN_{y}), and the like. These can be used alone or in combination.

The first, second, and third active patterns ACT1, ACT2, and ACT3 as patterns of an active pattern layer may be disposed on the first insulating layer IL1. In an embodiment, each of the first, second, and third active patterns ACT1, ACT2, and ACT3 may include a metal oxide semiconductor, an inorganic semiconductor (e.g., amorphous silicon, poly silicon, and the like), or an organic semiconductor. The first, second, and third active patterns ACT1, ACT2, and ACT3 may be formed (or provided) through the same process and may include the same material.

The metal oxide semiconductor may include a binary compound (ABₓ), a ternary compound (ABₓC_{y}), a quaternary compound (ABₓC_{y}D_{z}), and the like containing indium (In), zinc (Zn), gallium (Ga), tin (Sn), titanium (Ti), aluminum (Al), hafnium (Hf), zirconium (Zr), magnesium (Mg), and the like. For example, the metal oxide semiconductor may include zinc oxide (e.g., ZnO or ZnO₂), gallium oxide (GaOₓ), tin oxide (SnOₓ), indium oxide (InOₓ), indium gallium oxide (IGO), indium zinc oxide (IZO), indium tin oxide (ITO), indium zinc tin oxide (IZTO), indium gallium zinc oxide (IGZO), and the like. These can be used alone or in combination with each other.

Each of the first, second, and third active patterns ACT1, ACT2, and ACT3 may include a source region, a drain region, and a channel region located between the source region and the drain region. For example, the source region and the drain region may be doped with impurities (e.g., P-type impurities or N-type impurities), and the channel region may not be doped with impurities.

The second insulating layer IL2 may be disposed on the first insulating layer IL1. The second insulating layer IL2 may sufficiently cover the first, second, and third active patterns ACT1, ACT2, and ACT3, and may have a substantially flat upper surface without creating steps around the first, second, and third active patterns ACT1, ACT2, and ACT3. Alternatively, the second insulating layer IL2 may cover the first, second, and third active patterns ACT1, ACT2, and ACT3 and may be disposed along the profile of each of the first, second, and third active patterns ACT1, ACT2, and ACT3 with a uniform thickness. For example, the second insulating layer IL2 may include an inorganic material such as silicon oxide (SiOₓ), silicon nitride (SiNₓ), silicon carbide (SiCx), silicon oxynitride (SiOₓN_{y}), silicon oxycarbide (SiOₓC_{y}), and the like. These can be used alone or in combination with each other.

The first, second, and third gate electrodes GE1, GE2, and GE3 as patterns of a gate electrode layer may be disposed on the second insulating layer IL2. The first gate electrode GE1 may overlap the channel region of the first active pattern ACT1, the second gate electrode GE2 may overlap the channel region of the second active pattern ACT2, and the third gate electrode GE3 may overlap the channel region of the third active pattern ACT3. The first to third gate electrodes GE1, GE2, and GE3 may be formed through the same process and may include the same material.

Each of the first, second, and third gate electrodes GE1, GE2, and GE3 may include metal, alloy metal nitride, conductive metal oxide, transparent conductive material, and the like. Examples of the metal may include silver (Ag), molybdenum (Mo), aluminum (Al), tungsten (W), copper (Cu), nickel (Ni), chromium (Cr), titanium (Ti), tantalum (Ta), platinum (Pt), scandium (Sc), and the like. Examples of the conductive metal oxide may include indium tin oxide, indium zinc oxide, and the like. In addition, examples of the metal nitride may include aluminum nitride (AlNx), tungsten nitride (WNx), chromium nitride (CrNx), and the like. These can be used individually or in combination with each other.

The third insulating layer IL3 may be disposed on the second insulating layer IL2. The third insulating layer IL3 may sufficiently cover the first, second, and third gate electrodes GE1, GE2, and GE3, and may a substantially flat upper surface without creating step around the first, second, and third gate electrodes GE1, GE2, and GE3 (e.g., planarize the gate electrode layer). Alternatively, the third insulating layer IL3 may cover the first, second, and third gate electrodes GE1, GE2, and GE3, and may disposed along the profile of each of the first, second, and third gate electrodes GE1, GE2, and GE3 with a uniform thickness. For example, the third insulating layer IL3 may include an inorganic material such as silicon oxide, silicon nitride, silicon carbide, silicon oxynitride, silicon oxycarbide, and the like. These can be used alone or in combination with each other.

The first, second, and third source electrodes SE1, SE2, and SE3 may be disposed on the third insulating layer IL3. The first source electrode SE1 may be connected to the source region of the first active pattern ACT1 through a contact hole penetrating a thickness of the second and third insulating layers IL2 and IL3. The second source electrode SE2 may be connected to the source region of the second active pattern ACT2 through a contact hole penetrating the thickness of the second and third insulating layers IL2 and IL3. The third source electrode SE3 may be connected to the source region of the third active pattern ACT3 through a contact hole penetrating the thickness of the second and third insulating layers IL2 and IL3.

The first, second, and third drain electrodes DE1, DE2, and DE3 may be disposed on the third insulating layer IL3. The first drain electrode DE1 may be connected to the drain region of the first active pattern ACT1 through a contact hole penetrating the thickness of the second and third insulating layers IL2 and IL3. It may be connected to the drain region of the second active pattern ACT2 through a contact hole penetrating the thickness of the second and third insulating layers IL2 and IL3. The third drain electrode DE3 may be connected to the drain region of the third active pattern ACT3 through a contact hole penetrating the thickness of the second and third insulating layers IL2 and IL3.

For example, each of the first, second, and third source electrodes SE1, SE2, and SE3 as patterns of a source electrode layer may include metal, alloy, metal nitride, conductive metal oxide, transparent conductive material, and the like. These can be used alone or in combination with each other. The first, second, and third drain electrodes DE1, DE2, and DE3 as patterns of a drain electrode layer may be formed through the same process as the first, second, and third source electrodes SE1, SE2, and SE3, and may include the same material as the first, second, and third source electrodes SE1, SE2, and SE3. Here, the various source electrodes and the various drain electrodes may be in a same layer as each other. As being in a same layer, elements may be formed in a same process and/or include a same material as each other, elements may be respective portions of a same material layer, elements may be on a same layer by forming an interface with a same underlying or overlying layer, elements may be coplanar with each other or be disposed in a same thickness, etc., without being limited thereto.

The fourth insulating layer IL4 may be disposed on the third insulating layer IL3. The fourth insulating layer IL4 may sufficiently cover the first, second, and third source electrodes SE1, SE2, and SE3 and the first, second, and third drain electrodes DE1, DE2, and DE3. The fourth insulating layer IL4 may include an organic material. For example, the fourth insulating layer IL4 may include phenolic resin, polyacrylates resin, polyimides rein, polyamides resin, siloxane resin, epoxy resin, and the like. These can be used alone or in combination with each other.

The first, second, and third pixel electrodes PE1, PE2, and PE3 as patterns of a pixel electrode layer may be disposed on the fourth insulating layer IL4. The first pixel electrode PE1 may overlap the first light-emitting area EA1, the second pixel electrode PE2 may overlap the second light-emitting area EA2, and the third pixel electrode PE3 may overlap the third light-emitting area EA3. The first pixel electrode PE1 may be connected to the first drain electrode DE1 (or the first source electrode SE1) through a contact hole penetrating a thickness of the fourth insulating layer IL4 and the second pixel electrode PE2 may be connected to the second drain electrode DE2 (or the second source electrode SE2) through a contact hole penetrating the thickness of the fourth insulating layer IL4. In addition, the third pixel electrode PE3 may be connected to the third drain electrode DE3 (or third source electrode SE3) through a contact hole penetrating the thickness of the fourth insulating layer IL4. For example, each of the first, second, and third pixel electrodes PE1, PE2, and PE3 may function as an anode electrode.

For example, each of the first, second, and third pixel electrodes PE1, PE2, and PE3 may include metal, alloy, metal nitride, conductive metal oxide, transparent conductive material, and the like. These can be used alone or in combination with each other. In an embodiment, each of the first, second, and third pixel electrodes PE1, PE2, and PE3 may have a three-layer structure including ITO/Ag/ITO. However, embodiments of the present disclosure are not necessarily limited thereto.

The pixel defining layer PDL may be disposed on the fourth insulating layer IL4 and the first, second, and third pixel electrodes PE1, PE2, and PE3. A material portion (e.g., solid material) of the pixel defining layer PDL may overlap the non-light emitting area NEA. The pixel defining layer PDL may cover the edges of each of the first, second, and third pixel electrodes PE1, PE2, and PE3 and the material portion of the pixel defining layer PDL may define pixel openings which expose at least a portion of an upper surface of each of the first, second, and third pixel electrodes PE1, PE2, and PE3 to outside the pixel defining layer PDL. The pixel defining layer PDL may include organic and/or inorganic materials. In an embodiment, the pixel defining layer PDL may include an organic material. For example, the pixel defining layer PDL may include photoresist, polyacrylic resin, polyimide resin, polyamide resin, siloxane resin, acrylic resin, epoxy resin, and the like. These can be used alone or in combination with each other.

A light-emitting layer and a functional layer may be disposed on the pixel defining layer PDL and on the first, second, and third pixel electrodes PE1, PE2, and PE3. First, the first, second, and third hole transport regions HTR1, HTR2, and HTR3 may be disposed on the pixel defining layer PDL and on the first, second, and third pixel electrodes PE1, PE2, and PE3. The first hole transport region HTR1 may overlap the first light-emitting area EA1, the second hole transport region HTR2 may overlap the second light-emitting area EA2, and the third hole transport region HTR3 may overlap the third light-emitting area EA3. In an embodiment, the first, second, and third hole transport regions HTR1, HTR2, and HTR3 may be integrally formed in the first, second, and third light-emitting areas EA1, EA2, and EA3 and the non-light emitting area NEA on the pixel defining layer PDL and the first, second, and third pixel electrodes PE1, PE2, and PE3, and may be provided as one common layer. However, embodiments of the present disclosure are not necessarily limited to this, and the first, second, and third hole transport regions HTR1, HTR2, and HTR3 may be disposed to be spaced apart from each other.

For example, the first, second, and third hole transport regions HTR1, HTR2, and HTR3 may include carbazole-based derivatives such as N-phenylcarbazole and polyvinylcarbazole, fluorene-based derivatives, triphenylamine-based derivatives such as TPD(N,N′-bis(3-methylphenyl)-N,N′-diphenyl-[1,1-biphenyl]-4,4′-diamine) and TCTA(4,4′,4″-tris(N-carbazolyl)triphenylamine), NPD(N,N′-di(naphthalene-1-yl)-N,N′-diphenyl-benzidine), TAPC(4,4′-Cyclohexylidenebis[N,Nbis(4-methylphenyl)benzenamine]), HMTPD(4,4′-Bis[N,N′-(3-tolyl)amino]-3,3′-dimethylbiphenyl), mCP(1,3-Bis(N-carbazolyl)benzene), and the like. These can be used alone or in combination with each other. However, embodiments of the present disclosure are not necessarily limited thereto.

The first hole transport region HTR1 may include a first hole injection layer HIL1 as a first hole injection sub-layer and a first hole transport layer HTL1 as a first hole transport sub-layer which is disposed on the first hole injection layer HIL1. The second hole transport region HTR2 may include a second hole injection layer HIL2 as a second hole injection sub-layer and a second hole transport layer HTL2 as a second hole transport layer which is disposed on the second hole injection layer HIL2. The third hole transport region HTR3 may include a third hole injection layer HIL3 as a third hole injection sub-layer and a third hole transport layer HTL3 as a third hole transport sub-layer which is disposed on the third hole injection layer HIL3.

The first, second, and third hole injection layers HIL1, HIL2, and HIL3 of a hole injection layer may improve hole injection characteristics into the first, second, and third hole transport layers HTL1, HTL2, and HTL3 of a hole transport layer without increasing the driving voltage. Alternatively, the first, second, and third hole injection layers HIL1, HIL2, and HIL3 may be omitted.

Each of the first, second, and third hole transport layers HTL1, HTL2, and HTL3 may serve to facilitate injection of holes from a pixel electrode (e.g., the first pixel electrode PE1, the second pixel electrode PE2, or the third pixel electrode PE3) to a light-emitting layer (e.g., the first light-emitting layer EML1, the second light-emitting layer EML2, or the third light-emitting layer EML3).

The first light-emitting layer EML1 may be disposed on the first hole transport region HTR1, the second light-emitting layer EML2 may be disposed on the second hole transport region HTR2, and the third light-emitting layer EML3 may be disposed on the third hole transport region HTR3. The first light-emitting layer EML1 may overlap the first light-emitting area EA1, the second light-emitting layer EML2 may overlap the second light-emitting area EA2, and the third light-emitting layer EML3 may overlap the third light-emitting area EA3.

For example, each of the first, second, and third light-emitting layers EML1, EML2, and EML3 may include a pattern of a light-emitting material (e.g., an organic material) which emits light of a preset color. In an embodiment, the first light-emitting layer EML1 may include a light-emitting material which emits light L1 of a first color, the second light-emitting layer EML2 may include a light-emitting material which emits light L2 of a second color, and the third light-emitting layer EML3 may include a light-emitting material which emits light L3 of a third color. For example, the first color may be red, the second color may be green, and the third color may be blue. However, the present disclosure is not necessarily limited thereto.

The first light-emitting element LED1 may further include a first auxiliary hole transport layer (not shown) disposed between the first hole transport layer HTL1 and the first light-emitting layer EML1. The first auxiliary hole transport layer may control the resonance period of light emitted from the first light-emitting layer EML1. Likewise, the second light-emitting element LED2 may further include a second auxiliary hole transport layer (not shown) between the second hole transport layer HTL2 and the second light-emitting layer EML2. The second auxiliary hole transport layer may control the resonance period of light emitted from the second light-emitting layer EML2.

The first light-emitting element LED1 may further include a first auxiliary layer (not shown) disposed between the first auxiliary hole transport layer and the first light-emitting layer EML1. The first auxiliary layer may improve the light generation efficiency of the first light-emitting layer EML1 by controlling the hole charge balance. Likewise, the third light-emitting element LED3 may further include a second auxiliary layer (not shown) disposed between the third hole transport layer HTL3 and the third light-emitting layer EML3. The second auxiliary layer may improve the light generation efficiency of the third light-emitting layer EML3 by controlling the hole charge balance.

The first electron transport layer ETL1 may be disposed on the first light-emitting layer EML1, the second electron transport layer ETL2 may be disposed on the second light-emitting layer EML2, and the third electron transport layer ETL3 may be disposed on the third light-emitting layer EML3. The first electron transport layer ETL1 may overlap the first light-emitting area EA1, the second electron transport layer ETL2 may overlap the second light-emitting area EA2, and the third electron transport layer ETL3 may overlap the third light-emitting area EA3. In an embodiment, the first, second, and third electron transport layers ETL1, ETL2, and ETL3 of an electron transport material layer may be integrally formed in the first, second, and third light-emitting areas EA1, EA2, and EA3 and the non-light emitting area NEA on the first, second, and third light-emitting layers EML1, EML2, and EML3 and on the first, second, and third hole transport regions HTR1, HTR2, and HTR3 and may be provided as one common layer. However, embodiments of the present disclosure are not necessarily limited to this, and the first, second, and third electron transport layers ETL1, ETL2, and ETL3 may be disposed as discrete patterns which are spaced apart from each other along the substate SUB.

The first, second, and third electron transport layers ETL1, ETL2, and ETL3 may transfer electrons from the first, second, and third common electrodes CE1, CE2, and CE3 to the light-emitting layer. For example, the first, second, and third electron transport layers ETL1,

ETL2, and ETL3 may include inorganic particles, peroxides, hydrocarbon compounds, and solvents. The inorganic particles may serve to transport electrons injected from the first, second, and third common electrodes CE1, CE2, and CE3. The inorganic particles may include metal oxide. For example, the metal oxide may include a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, NiO, SnO₂, Ta₂O₃, ZrO₂, HfO₂, Y₂O₃, and the like, or a ternary compounds such as ZnMgO, MgAl₂O₄, CoFe₂O₄, NiFe₂O₄, CoMn₂O₄, BaTiO₃, BaZrO₃, ZrSiO₄, and the like. These can be used alone or in combination with each other. However, embodiments of the present disclosure are not necessarily limited thereto.

The first, second, and third light-emitting elements LED1, LED2, and LED3 may further include a buffer layer (not shown) disposed between the first, second, and third light-emitting layers EML1, EML2, and EML3 and the first, second, and third electron transport layers ETL1, ETL2, and ETL3, respectively. The buffer layer may prevent holes from passing from the first, second, and third light-emitting layers EML1, EML2, and EML3 to the first, second, and third common electrodes CE1, CE2, and CE3.

The first electron injection layer EIL1 may be disposed on the first electron transport layer ETL1, the second electron injection layer EIL2 may be disposed on the second electron transport layer ETL2, and the third electron injection layer EIL3 may be disposed on the third electron transport layer ETL3. The first electron injection layer EIL1 may overlap the first light-emitting area EA1, the second electron injection layer EIL2 may overlap the second light-emitting area EA2, and the third electron injection layer EIL3 may overlap the third light-emitting area EA3. In an embodiment, the first, second, and third electron injection layers EIL1, EIL2, and EIL3 may be disposed to be spaced apart from each other.

The first, second, and third electron injection layers EIL1, EIL2, and EIL3 of an electron injection material layer may improve electron injection characteristics into the first, second, and third electron transport layers ETL1, ETL2, and ETL3 without increasing the driving voltage. For example, the first, second, and third electron injection layers EIL1, EIL2, and EIL3 may include a lanthanum-based metal material such as ytterbium (Yb), samarium (Sm), europium (Eu), and the like. That is, the first, second, and third electron injection layers EIL1, EIL2, and EIL3 may include a lanthanum metal material. Alternatively, the first, second, and third electron injection layers EIL1, EIL2, and EIL3 may simultaneously include a metal halide material such as RbI:Yb, KI:Yb, and the like and a lanthanum-based metal material. In this case, the first, second, and third electron injection layers EIL1, EIL2, and EIL3 may be formed by co-depositing a metal halide material and a lanthanum-based metal material. Alternatively, the first, second, and third electron injection layers EIL1, EIL2, and EIL3 may include a metal halide material such as MgF2, LiF, NaF, KF, RbF, CsF, FrF, LiI, NaI, KI, RbI, CsI, FrI, CaF2, and the like. In an embodiment, the first, second, and third electron injection layers EIL1, EIL2, and EIL3 may include Yb.

The first electron injection layer EIL1 may have a first thickness TH1, the second electron injection layer EIL2 may have a second thickness TH2, and the third electron injection layer EIL3 may have a third thickness TH3. In an embodiment, the first thickness TH1 may be thicker (e.g., greater) than each of the second thickness TH2 and the third thickness TH3, and the second thickness TH2 and the third thickness TH3 may be equal to each other. However, embodiments of the present disclosure are not necessarily limited to this, and the first thickness TH1 may be greater than each of the second thickness TH2 and the third thickness TH3, and the second thickness TH2 and the third thickness TH3 may be different from each other.

The various thicknesses of the electron injection material layer may be a maximum thickness of the material layer at a respective emission area. Each of the first, second, and third thicknesses TH1, TH2, and TH3 may range from about 1 angstrom (Å) to about 100 angstrom (Å). In an embodiment, each of the first, second, and third thicknesses TH1, TH2, and TH3 may range from about 3 angstroms (Å) to about 90 angstroms (Å). In an embodiment, when the first, second, and third electron injection layers EIL1, EIL2, and EIL3 include ytterbium (Yb), each of the first, second, and third thicknesses TH1, TH2, and TH3 may range from about 7.5 angstroms (Å) to about 18.5 Angstroms (Å). When each of the first, second, and third thicknesses TH1, TH2, and TH3 satisfies the range described above, satisfactory electron injection characteristics may be obtained without a substantial increase in the driving voltage.

For example, when the first, second, and third electron injection layers EIL1, EIL2, and EIL3 include ytterbium (Yb), the first thickness TH1 may be about 15 angstroms (Å), and each of the second thickness TH2 and the third thickness TH3 may be about 13 angstroms (Å).

In a comparative example, when the first thickness TH1, the second thickness TH2, and the third thickness TH3 are equal to each other (e.g., when each of the first thickness TH1, the second thickness TH2, and the third thickness TH3 is about 13 angstroms (Å)), the image displayed by the display device DD including the light blocking layer BM and the first, second, and third color filters CF1, CF2, and CF3 may be displayed as bluish when the viewing angle is high (e.g., about 60 degrees).

As in an embodiment of the present disclosure, when the first thickness TH1 is greater than each of the second thickness TH2 and the third thickness TH3, and the second thickness TH2 and the third thickness TH3 are equal to each other, the bluish display of the image by the display device DD including the light blocking layer BM and the first, second, and third color filters CF1, CF2, and CF3 may be minimized or reduced when the viewing angle is high (e.g., about 60 degrees).

The first common electrode CE1 may be disposed on the first electron injection layer EIL1, the second common electrode CE2 may be disposed on the second electron injection layer EIL2, and the third common electrode CE3 may be disposed on the third electron injection layer EIL3. The first common electrode CE1 may overlap the first light-emitting area EA1, the second common electrode CE2 may overlap the second light-emitting area EA2, and the third common electrode CE3 may overlap the third light-emitting area EA3. In an embodiment, the first, second, and third common electrodes CE1, CE2, and CE3 of a common electrode layer may be integrally formed in the first, second, and third light-emitting areas EA1, EA2, and EA3 and the non-light emitting area NEA on the first, second, and third electron injection layers EIL1, EIL2, and EIL3 and the first, second, and third electron transport layers ETL1, ETL2, and ETL3, and may be provided as one common layer. However, embodiments of the present disclosure are not necessarily limited to this, and the first, second, and third common electrodes CE1, CE2, and CE3 may be disposed to be spaced apart from each other.

For example, the first, second, and third common electrodes CE1, CE2, and CE3 may include metal, alloy, metal nitride, conductive metal oxide, transparent conductive material, and the like. These can be used alone or in combination with each other.

The capping layer CL may be disposed on the first, second, and third common electrodes CE1, CE2, and CE3. The capping layer CL may be disposed in an entirety of the first, second, and third light-emitting areas EA1, EA2, and EA3 and in the non-light emitting area NEA, on the first, second, and third common electrodes CE1, CE2, and CE3. The capping layer CL may function to protect the first, second, and third common electrodes CE1, CE2, and CE3. For example, the capping layer CL may include an organic material and/or an inorganic material.

The encapsulation layer ENC may be disposed on the capping layer CL. The encapsulation layer ENC may prevent impurities, moisture, and the like from penetrating into the first, second, and third light-emitting elements LED1, LED2, and LED3 of a light-emitting element layer, from the outside (e.g., the outside of the display device DD). The encapsulation layer ENC may include at least one inorganic encapsulation layer and at least one organic encapsulation layer.

The touch sensing layer TCL may be disposed on the encapsulation layer ENC. The touch sensing layer TCL may function as an input means of the display device DD, that is, sending an external input to the display device DD via an input tool. The touch sensing layer TCL may include a first touch insulating layer TIL1, a second touch insulating layer TIL2, a first touch electrode TE1, a second touch electrode TE2, and a protective layer PL.

The first touch insulating layer TIL1 may be disposed on the encapsulation layer ENC. The first touch insulating layer TIL1 may include an inorganic material or an organic material. For example, the first touch insulating layer TIL1 may include an inorganic material such as silicon oxide, silicon nitride, and the like. These can be used alone or in combination with each other.

The first touch electrode TE1 may be disposed on the first touch insulating layer TIL1. For example, the first touch electrode TE1 may include metal, alloy, metal nitride, conductive metal oxide, transparent conductive material, and the like. These can be used alone or in combination with each other.

The second touch insulating layer TIL2 may be disposed on the first touch insulating layer TIL1 and the first touch electrode TE1. The second touch insulating layer TIL2 may sufficiently cover the first touch electrode TE1. The second touch insulating layer TIL2 may include an inorganic material or an organic material. For example, the second touch insulating layer TIL2 may include an inorganic material such as silicon oxide, silicon nitride, and the like. These can be used alone or in combination with each other.

The second touch electrode TE2 may be disposed on the second touch insulating layer TIL2. The second touch electrode TE2 may be connected to the first touch electrode TE1 through a contact hole penetrating a thickness of the second touch insulating layer TIL2. For example, the second touch electrode TE2 may include carbon nanotube (CNT), transparent conductive oxide, indium tin oxide (ITO), indium gallium zinc oxide (IGZO), zinc oxide (ZnO), graphene, Ag nanowire (AgNW), copper (Cu), chromium (Cr), and the like. These can be used alone or in combination with each other.

For example, the first touch electrode TE1 of a first touch electrode layer and the second touch electrode TE2 of a second touch electrode layer may include the same material as each other. Alternatively, the first touch electrode TE1 and the second touch electrode TE2 may include different materials from each other.

The protective layer PL may be disposed on the second touch insulating layer TIL2 and the second touch electrode TE2. The protective layer PL may sufficiently cover the second touch electrode TE2. The protective layer PL may protect the first touch electrode TEL and the second touch electrode TE2. The protective layer PL may include an inorganic material or an organic material. For example, the protective layer PL may include an inorganic material such as silicon oxide, silicon nitride, and the like. These can be used alone or in combination with each other.

The light blocking layer BM as a material pattern may be disposed on the protective layer PL. Solid (or material) portions of the light blocking layer BM may overlap the non-light emitting area NEA and be spaced apart from each other to define openings corresponding to those of the pixel openings defined in the pixel defining layer PDL, without being limited thereto. The light blocking layer BM may block light incident on the light blocking layer BM. Accordingly, the light blocking layer BM may prevent color mixing between the first light-emitting area EA1, the second light-emitting area EA2, and the third light-emitting area EA3. First, second, and third openings overlapping the first, second, and third light-emitting areas EA1, EA2, and EA3 may be defined in the light blocking layer BM. For example, the light blocking layer BM may include an organic material and/or an inorganic material containing black pigment, black dye, and the like. In an embodiment, the light blocking layer BM may include a black matrix material.

The first, second, and third color filters CF1, CF2, and CF3 may be disposed on the protective layer PL. The first, second, and third color filters CF1, CF2, and CF3 may selectively transmit light of a specific color.

The first color filter CF1 may be disposed to overlap the first light-emitting area EA1 and fill the first opening of the light blocking layer BM. The first color filter CF1 may selectively transmit the light L1 of the first color and block or absorb the light L2 of the second color and the light L3 of the third color. For example, the first color filter CF1 may be a red color filter and may include a red colorant.

The second color filter CF2 may be disposed to overlap the second light-emitting area EA2 and fill the second opening of the light blocking layer BM. The second color filter CF2 may selectively transmit the light L2 of the second color and block or absorb the light L1 of the first color and the light L3 of the third color. For example, the second color filter CF2 may be a green color filter and may include a green colorant.

The third color filter CF3 may be disposed to overlap the third light-emitting area EA3 and fill the third opening of the light blocking layer BM. The third color filter CF3 may selectively transmit the light L3 of the third color and block or absorb the light L1 of the first color and the light L2 of the second color. For example, the third color filter CF3 may be a blue color filter and may include a blue colorant.

As the display device DD includes the light blocking layer BM and the first, second, and third color filters CF1, CF2, and CF3, the display device DD may not include a polarizer. That is, the light blocking layer BM and the first, second, and third color filters CF1, CF2, and CF3 may replace the function of the polarizer. In other words, the light blocking layer BM together with the first, second, and third color filters CF1, CF2, and CF3 as providing a polarizer function may selectively absorb external light reflected at the inside of the display device DD according to the wavelength of the light, thereby preventing a decrease in light efficiency of the display device DD.

The overcoat layer OC may be disposed on the first, second, and third color filters CF1, CF2, and CF3. The overcoat layer OC may sufficiently cover the first, second, and third color filters CF1, CF2, and CF3. The overcoat layer OC may include a material with high light transmittance. For example, the overcoat layer OC may include an organic material. However, embodiments of the present disclosure are not necessarily limited thereto.

Hereinafter, the effects of the present disclosure according to Comparative Example 1 and Comparative Example 2 will be described.

In Comparative Example 1 and Comparative Example 2, a comparative display device including a first light-emitting element which emits light of red and including a first pixel electrode, a first hole injection layer, a first hole transport layer, a first light-emitting layer, a first electron transport layer, a first electron injection layer and a first common electrode, a second light-emitting element which emits light of green and including a second pixel electrode, a second hole injection layer, a second hole transport layer, a second light-emitting layer, a second electron transport layer, a second electron injection layer and a second common electrode, and a third light-emitting element which emits light of blue and including a third pixel electrode, a third hole injection layer, a third hole transport layer, a third light-emitting layer, a third electron transport layer, a third electron injection layer and a third common electrode was manufactured.

In the comparative display devices, the first, second, and third pixel electrodes were formed by stacking ITO/Ag/ITO. The first, second, and third light-emitting layers were formed using an organic light-emitting material commonly known in the art. The first, second, and third hole injection layers, the first, second, and third hole transport layers, and the first, second, and third electron transport layers were each formed using a material commonly known in the art. The first, second, and third electron injection layers were formed using Yb. The first, second, and third common electrodes were formed using Ag and Mg. The light blocking layer was formed using a black matrix material commonly known in the art. The first color filter is a red color filter commonly known in the art, the second color filter is a green color filter commonly known in the art, and the third color filter is a blue color filter commonly known in the art.

The thickness of each of the first, second, and third electron injection layers is shown in Table 1 below.

TABLE 1

| | The thickness of each of the first, second, |
|---|---|
| | and third electron injection layers |
| Comparative Example 1 | 13 angstroms (Å) |
| Comparative Example 2 | 15 angstroms (Å) |

In Comparative Examples 1 and 2, white efficiency, red luminance ratio (i.e., luminance ratio of light of red), green luminance ratio (i.e., luminance ratio of light of green), and blue luminance ratio (i.e., luminance ratio of light of blue) of the display device were measured. Here, each of the red luminance ratio, the green luminance ratio, and the blue luminance ratio refer to side luminance ratio when the viewing angle is about 60 degrees.

TABLE 2

| | White | Red | Green | Blue |
|---|---|---|---|---|
| | efficiency | luminance | luminance | luminance |
| | (%) | ratio | ratio | ratio |
| Comparative Example 1 | 100.5 | 0.154 | 0.163 | 0.151 |
| Comparative Example 2 | 98.9 | 0.177 | 0.165 | 0.156 |

As a result, it can be confirmed that the white efficiency of the comparative display device satisfying Comparative Example 1 is higher than the white efficiency of the comparative display device satisfying Comparative Example 2. In addition, it can be confirmed that the red luminance ratio of the display device satisfying Comparative Example 2 is greater than the red luminance ratio of the display device satisfying Comparative Example 1. That is, it can be confirmed that among the first, second, and third electron injection layers, an increase in the thickness of the first electron injection layer included in the first light-emitting element which emits light of red has the greatest influence on the change in the side luminance ratio.

As a result, in the display device DD according to an embodiment of the present disclosure, by making the first thickness TH1 of the first electron injection layer EILL disposed in the first light-emitting area EA1 which emits light of red greater than each of the second thickness TH2 of the second electron injection layer EIL2 disposed in the second light-emitting area EA2 which emits light of green and the third thickness TH3 of the third electron injection layer EIL3 disposed in the third light-emitting area EA3 which emits light of blue, the red luminance ratio may be relatively large when the viewing angle is high (e.g., about 60 degrees). Accordingly, when the viewing angle is a relatively high angle, the bluish display of the image of the display device DD may be minimized or reduced.

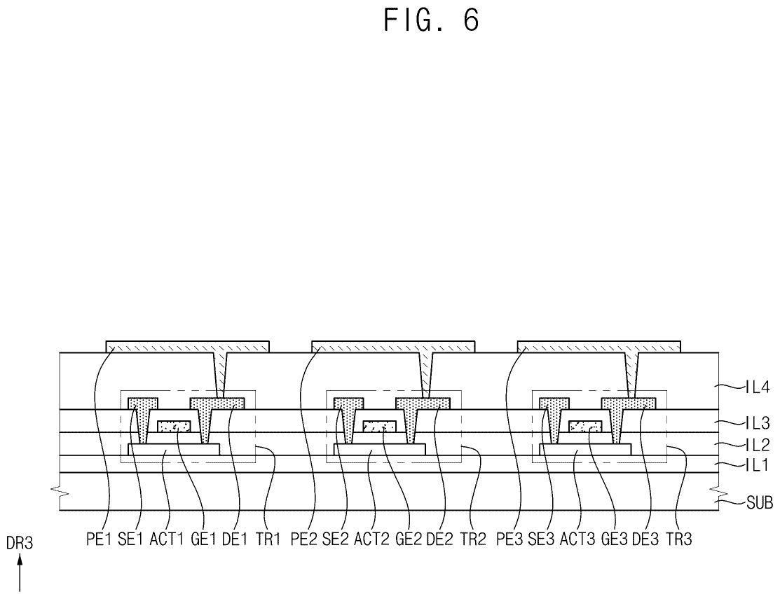

FIGS. 6, 7, 8, 9, 10, 11, and 12 are cross-sectional views for explaining a method for manufacturing (or providing) the display device DD of FIG. 2.

Referring to FIG. 6, the first insulating layer IL1, the first, second, and third active patterns ACT1, ACT2, and ACT3, the second insulating layer IL2, the first, second, and third gates electrodes GE1, GE2, and GE3, the third insulating layer IL3, the first, second, and third source electrodes SE1, SE2, and SE3, the first, second, and third drain electrodes DE1, DE2, and DE3, the fourth insulating layer IL4, and the first, second, and third pixel electrodes PE1, PE2, and PE3 may be sequentially formed (or provided) on the substrate SUB.

Accordingly, the first transistor TR1 including the first active pattern ACT1, the first gate electrode GE1, the first source electrode SE1 and the first drain electrode DE1 may be formed, the second transistor TR2 including the second active pattern ACT2, the second gate electrode GE2, the second source electrode SE2 and the second drain electrode DE2 may be formed, and the third transistor TR3 including the third gate electrode GE3, the third source electrode SE3 and the third drain electrode DE3 may be formed.

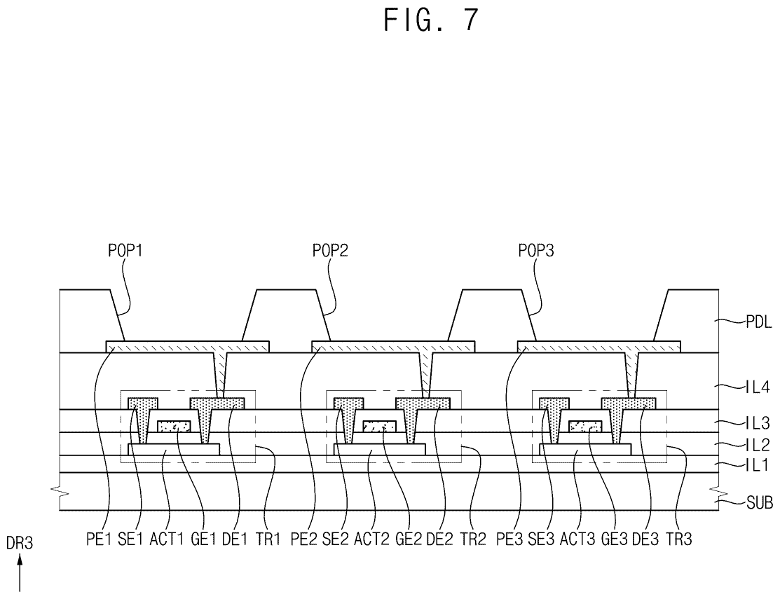

Referring to FIG. 7, the pixel defining layer PDL may be formed on the fourth insulating layer IL4 on the stacked structure of FIG. 6. A material portion of the pixel defining layer PDL may be formed to cover the edges of each of the first, second, and third pixel electrodes PE1, PE2, and PE3 and expose at least portion of the upper surface of each of the first, second, and third pixel electrodes PE1, PE2, and PE3 to outside the pixel defining layer PDL at pixel openings defined therein. Accordingly, the pixel defining layer PDL may be defined by a first pixel opening POP1 exposing the first pixel electrode PE1, a second pixel opening POP2 exposing the second pixel electrode PE2, and a third pixel electrode POP3 exposing the third pixel electrode PE3, together with the material portion which defines the pixel openings therein.

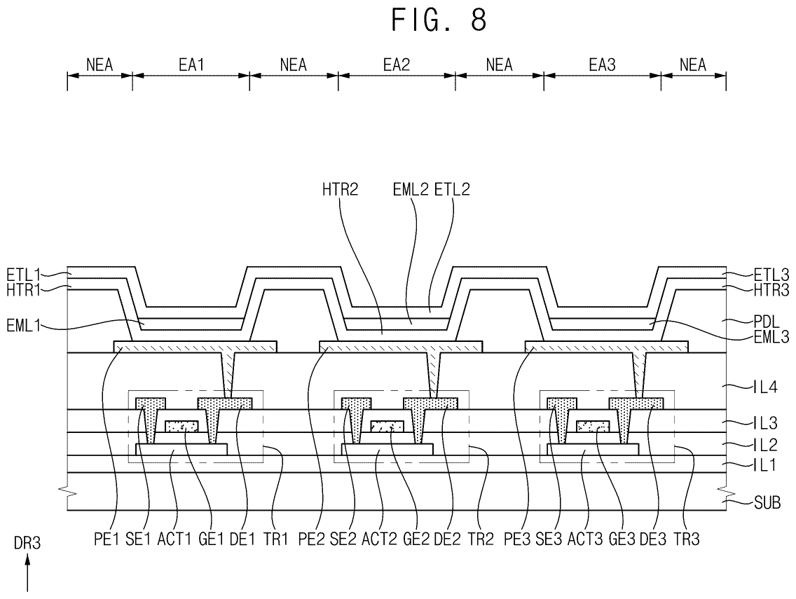

Referring to FIG. 8, the first, second, third hole transport regions HTR1, HTR2, and HTR3 of a hole transport layer may be formed on the pixel defining layer PDL and on the first, second, and third pixel electrodes PE1, PE2, and PE3. The first, second, third hole transport regions HTR1, HTR2, and HTR3 may be formed as one common layer which is continuously extended in the first, second, third light-emitting areas EA1, EA2, and EA3 and the non-light emitting area NEA. The hole transport layer may include sub-layers stacked along the third direction DR3, without being limited thereto.

The first light-emitting layer EML1 may be formed on the first hole transport region HTR1, the second light-emitting layer EML2 may be formed on the second hole transport region HTR2, and the third light-emitting layer EML3 may be formed on the third hole transport region HTR3. Specifically, the first, second, and third light-emitting layers EML1, EML2, and EML3 may be formed in the first, second, and third pixel openings POP1, POP2, and POP3, respectively. Each of the light-emitting layers may be a pattern, such as a discrete pattern, without being limited thereto.

The first, second, and third electron transport layers ETL1, ETL2, and ETL3 of an electron transport layer may be formed on the first, second, and third hole transport regions HTR1, HTR2, and HTR3 and on the first, second, and third light-emitting layers EML1, EML2, and EML3. The first, second, and third electron transport layers ETL1, ETL2, and ETL3 may be formed as one common layer in the first, second, and third light-emitting areas EA1, EA2, and EA3 and the non-light emitting area NEA (e.g., a continuous layer).

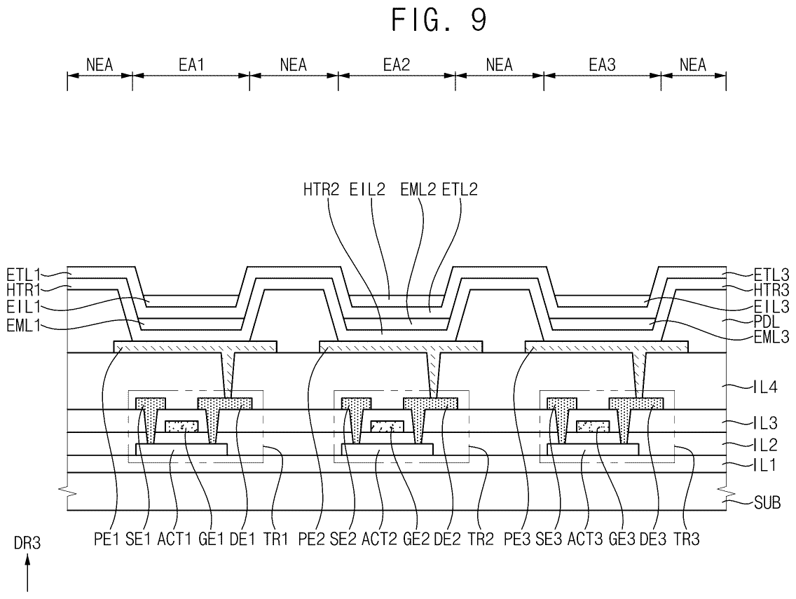

Referring to FIG. 9, the first electron injection layer EIL1 may be formed on the first electron transport layer ETL1, the second electron injection layer EIL2 may be formed on the second electron transport layer ETL2, and the third electron injection layer EIL3 may be formed on the third electron transport layer ETL3. Specifically, the first, second, and third electron injection layers EIL1, EIL2, and EIL3 may be formed in the first, second, and third pixel openings POP1, POP2, and POP3, respectively. Here, a stacked structure within a respective pixel opening (or a respective light emission area) may have a total thickness which is less than a total depth of the respective pixel opening which is measured from the upper surface of a respective pixel electrode.

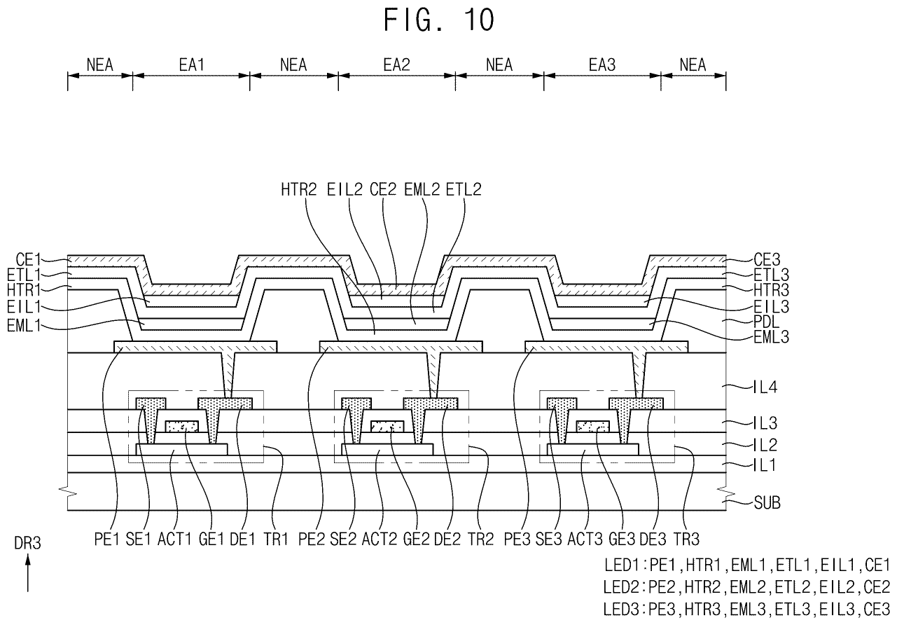

Referring to FIG. 10, the first, second, and third common electrodes CE1, CE2, and CE3 of a common electrode layer may be formed on the first, second, and third electron transport layers ETL1, ETL2, and ETL3 and on the first, second, and third electron injection layers EIL1, EIL2, and EIL3. The first, second, and third common electrodes CE1, CE2, and CE3 may be formed as one common layer in the first, second, and third light-emitting areas EA1, EA2, and EA3 and the non-light emitting area NEA.

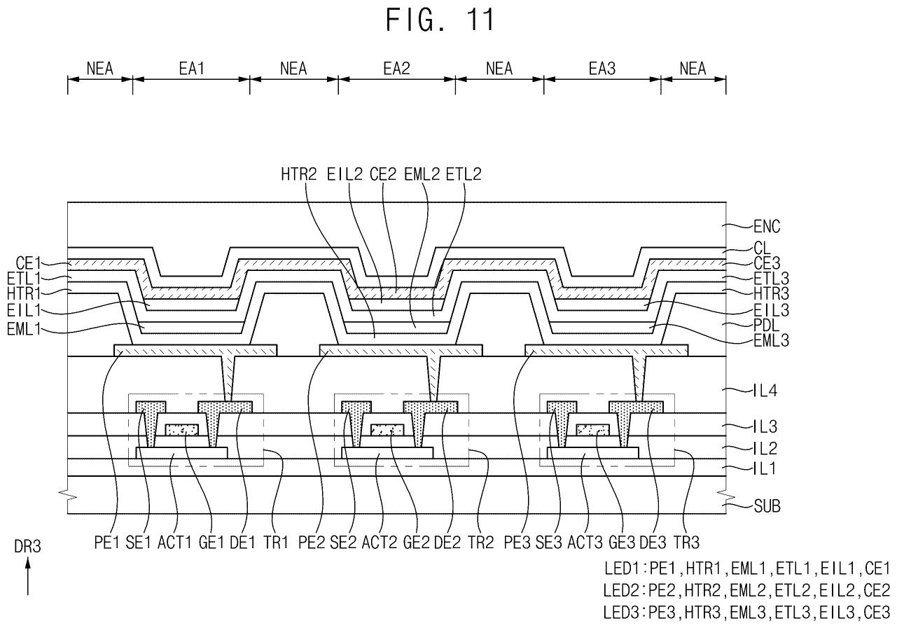

Referring to FIG. 11, the capping layer CL may be formed on the first, second, and third common electrodes CE1, CE2, and CE3. The capping layer CL may be formed in an entirety of the first, second, and third light-emitting areas EA1, EA2, and EA3 and the non-light emitting area NEA, on the first, second, and third common electrodes CE1, CE2, and CE3.

The encapsulation layer ENC may be formed on the capping layer CL. The encapsulation layer ENC may be formed in an entirety of the first, second, and third light-emitting areas EA1, EA2, and EA3 and the non-light emitting area NEA, on the capping layer CL. The encapsulation layer ENC may include at least one inorganic layer and at least one organic layer.

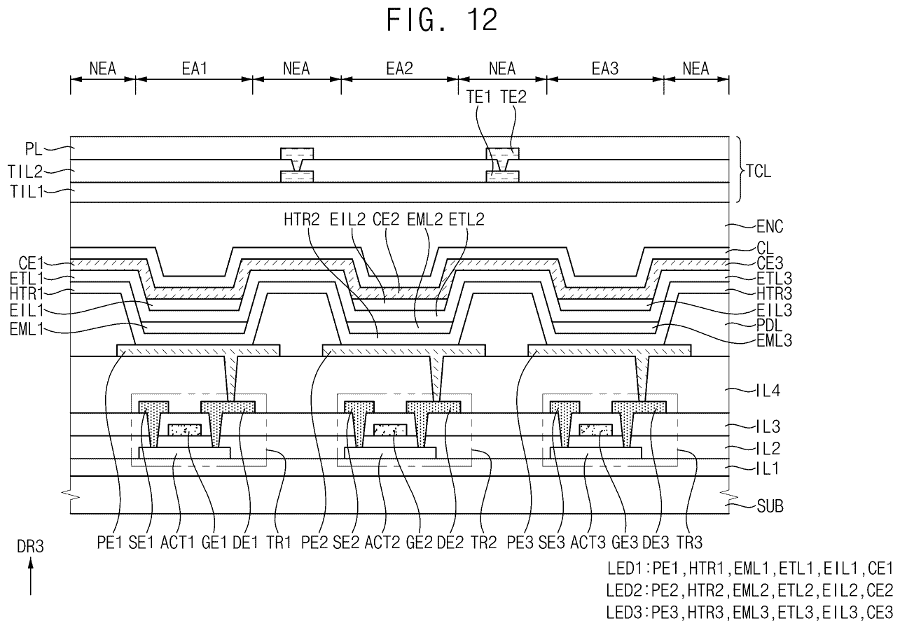

Referring to FIG. 12, the touch sensing layer TCL including the first touch insulating layer TIL1, the first touch electrode TE1, the second touch insulating layer TIL2, the second touch electrode TE2, and the protective layer PL sequentially formed on the encapsulation layer ENC may be formed.

Referring again to FIG. 2, the light blocking layer BM may be formed on the touch sensing layer TCL of FIG. 12. The light blocking layer BM may be formed in the non-light emitting area NEA.

The first, second, and third color filters CF1, CF2, and CF3 may be formed on the touch sensing layer TCL. The first color filter CF1 may be formed in the first light-emitting area EA1 and may cover at least a portion of the light blocking layer BM. The second color filter CF2 may be formed in the second light-emitting area EA2 and may cover at least a portion of the light blocking layer BM. The third color filter CF3 may be formed in the third light-emitting area EA3 and may cover at least a portion of the light blocking layer BM.

The overcoat layer OC may be formed on the first, second, and third color filters CF1, CF2, and CF3. The overcoat layer OC may sufficiently cover the first, second, and third color filters CF1, CF2, and CF3. The overcoat layer OC may be formed entirely in the first, second, and third light-emitting areas EA1, EA2, and EA3 and the non-light emitting area NEA on the first, second, and third color filters CF1, CF2, and CF3.

Accordingly, the display device DD of FIG. 2 may be manufactured.

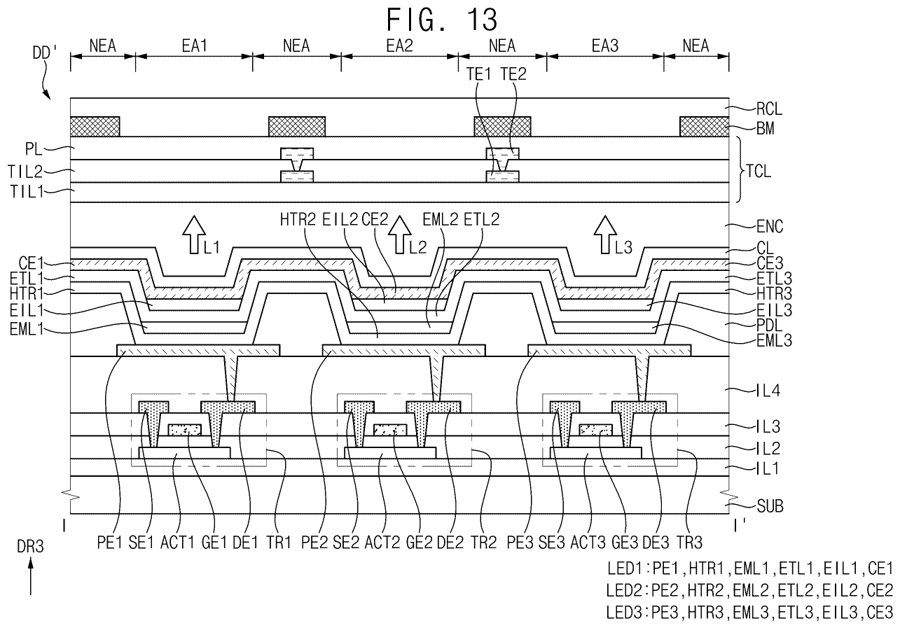

FIG. 13 is a cross-sectional view showing a display device DD′ according to an embodiment of the present disclosure.

Referring to FIG. 13, a display device DD′ according to an embodiment of the present disclosure may include a substrate SUB, first, second, and third transistors TR1, TR2, and TR3, first, second, third, and fourth insulating layers IL1, IL2, IL3, and IL4, a pixel defining layer PDL, first, second, and third light-emitting elements LED1, LED2, and LED3, a capping layer CL, an encapsulation layer ENC, a touch sensing layer TCL, a light blocking layer BM, and a reflection control layer RCL. However, the display device DD′ described with reference to FIG. 13 may be substantially the same as or similar to the described display device DD described with reference to FIG. 2 except that the display device DD′ includes the reflection control layer RCL instead of the first, second, and third color filters CF1, CF2, and CF3. Therefore, descriptions that overlap with those of the display device DD described with reference to FIG. 2 will be omitted or simplified.

The reflection control layer RCL may be disposed on the touch sensing layer TCL. The reflection control layer RCL may sufficiently cover the light blocking layer BM, such as extending along the light blocking layer BM and into the openings defined therein. As the display device DD′ includes the reflection control layer RCL, the display device DD′ may not include a polarizer. That is, the reflection control layer RCL may replace the function of the polarizer. In other words, the reflection control layer RCL as providing a polarizer function may prevent the light efficiency of the display device DD′ from being reduced by selectively absorbing external light reflected inside the display device DD′ according to the wavelength of the light.

In an embodiment, the reflection control layer RCL may include an inorganic material or an organic material, each of the inorganic material and the organic material containing dye, pigment, or a combination thereof.

For example, the maximum absorption light wavelength of the reflection control layer RCL may include a light wavelength range of about 530 nanometers (nm) to about 600 nm. That is, the reflection control layer RCL as a light wavelength absorbing layer may absorb light with a wavelength outside the wavelength range of red light, green light, or blue light which are respectively emitted from the first, second, and third light-emitting elements LED1, LED2, and LED3. Since the reflection control layer RCL is a continuous layer across light-emitting areas, the wavelength absorption may be applied across the light-emitting areas.

In an embodiment, a display device includes light-emitting areas including a first light-emitting area, a second light-emitting area and a third light-emitting area, and a non-light emitting area which is between the light-emitting areas, a hole transport layer in each of the light-emitting areas, light-emitting layers on the hole transport layer, the light-emitting layers including a first light-emitting layer which is in the first light-emitting area and emits light of a first color, a second light-emitting layer which is in the second light-emitting area and emits light of a second color different from the first color, and a third light-emitting layer which is in the third light-emitting area and emits light of a third color different from the first color and the second color, an electron transport layer on each of the light-emitting layers, and electron injection layers which are on the electron transport layer, the electron injection layers including a first electron injection layer which is in the first light-emitting area, faces the first light-emitting layer and has a first thickness, a second electron injection layer which is in the second light-emitting area, faces the second light-emitting layer and has a second thickness, and a third electron injection layer which is in the third light-emitting area, faces the third light-emitting layer and has a third thickness. The first color is red, the second color is green and the third color is blue. Among the electron injection layers, the first thickness of the first electron injection layer which is in the first light-emitting area is greater than each of the second thickness and the third thickness.

Th first electron injection layer, the second electron injection layer and the third electron injection layer may be spaced apart from each other along the electron transport layer, may include a lanthanum metal material or may include both a metal halide material and a lanthanum metal material.

The electron transport layer or the hole transport layer may be continuously disposed as a common layer in the first light-emitting area, the second light-emitting area, the third light-emitting area and the non-light emitting area.

The hole transport layer may include a hole injection sub-layer, and a hole transport sub-layer on the hole injection sub-layer,

The display device may further include an encapsulation layer on the electron injection layers, the encapsulation layer including at least one organic layer and at least one inorganic layer, a light blocking layer which is on the encapsulation layer and overlaps the non-light emitting area, and a color filter layer which is on the light blocking layer, the color filter layer including a first color filter, a second color filter and a third color filter respectively in the first light-emitting area, the second light-emitting area and the third light-emitting area. An overcoat layer may be on the first color filter, the second color filter and the third color filter.

The display device may further include an encapsulation layer on the electron injection layers, the encapsulation layer including at least one organic layer and at least one inorganic layer, a light blocking layer which is on the encapsulation layer and overlaps the non-light emitting area, and a reflection control layer on the light blocking layer, the reflection control layer including an inorganic material containing dye, pigment or a combination thereof, or an organic material containing dye, pigment or combination thereof.

In an embodiment, a display device includes electron injection layers which are on the electron transport layer, where among the electron injection layers a first electron injection layer, a second electron injection layer and a third electron injection layer have a first thickness, a second thickness and a third thickness, respectively, and the first thickness of the first electron injection layer facing the first light-emitting layer which emits the red light is greater than each of the second thickness and the third thickness.

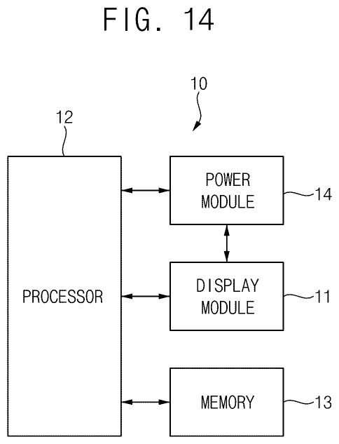

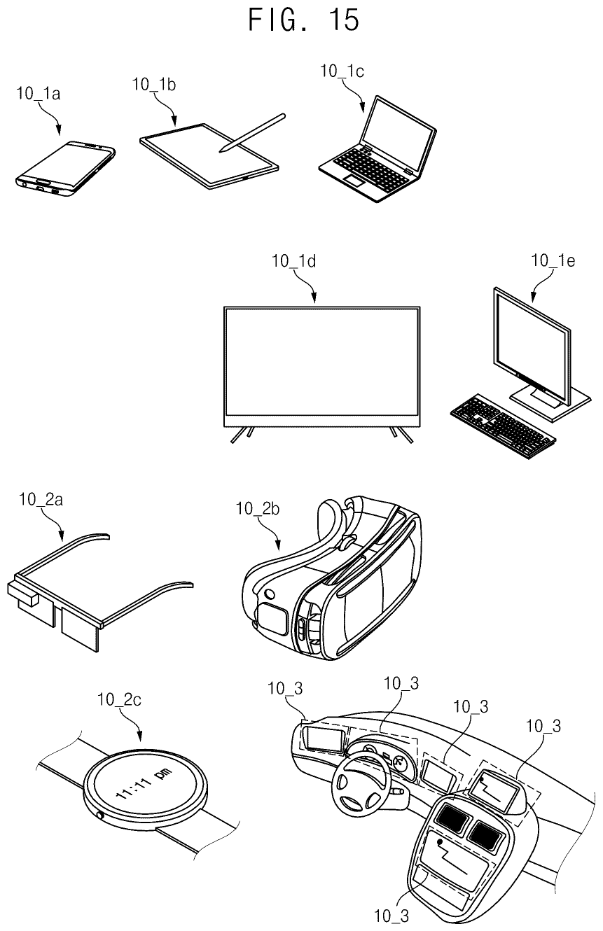

FIG. 14 is a block diagram showing an electronic device 10 according to embodiments of the present disclosure.

Referring to FIG. 14, an electronic device 10 may include a display module 11, a processor 12, a memory 13, and a power module 14.

A display device according to embodiments (e.g., the display device DD of FIG. 2 or the display device DD′ of FIG. 13) may be applied to various electronic devices 10. The electronic device 10 may include one of the display devices described above, and may further include modules or devices with additional functions other than the display device.

The processor 12 may include at least one of a central processing unit (CPU), an application processor (AP), a graphic processing unit (GPU), a communication processor (CP), an image signal processor (ISP), and a controller. The processor 12 may control the display device.

The memory 15 may store data information necessary for the operation of the processor 12 and/or the display module 11. When the processor 12 executes the application stored in the memory 15, an image data signal and/or an input control signal may be transmitted to the display module 11, and the display module 11 may process the received signal and output image information through a display screen.

The power module 14 may include a power supply module, such as a power adapter or a battery device, and a power conversion module which converts the power supplied by the power supply module to generate power required for the operation of the electronic device 10.

At least one of each component of the electronic device 10 described above may be included in the display device according to the above-described embodiments. In addition, some of the individual modules functionally included in one module may be included in the display device, and other portions may be provided separately from the display device. For example, the display device may include the display module 11, and the processor 12, the memory 13, and the power module 14 may be provided in the form of other devices within the electronic device 10 other than the display device.

FIG. 15 are schematic diagrams showing an electronic device 10 according to various embodiments.

Referring to FIG. 15, various electronic devices 10 to which display devices according to the embodiments (e.g., the display device DD of FIG. 2 or the display device DD′ of FIG. 13) are applied may include not only image display electronic devices such as a smartphone 10_1a, a tablet PC 10_1b, a laptop 10_1c, a television (TV) 10_1d, and a desktop monitor 10_1e, but also wearable electronic devices including display modules, such as smart glasses 10_2a, a head-mounted display 10_2b, and a smart watch 10_2c, automotive electronic devices 10_3 including display modules, such as a dashboard of a car, a center fascia, a Center Information Display (CID) disposed on a dashboard, and a room mirror display, or the like.

The present disclosure can be applied to various display devices. For example, the present disclosure is applicable to various display devices such as display devices for vehicles, ships and aircraft, portable communication devices, display devices for exhibition or information transmission, medical display devices, and the like.

In an embodiment, an electronic device includes a display device including a display area, and a processor which controls the display device. The display device includes in the display area, a light-emitting areas respectively emitting red light, green light and blue light, a non-light emitting area which is between the light-emitting areas. and in each of the light-emitting areas a hole transport layer, a light-emitting layer on the hole transport layer, an electron transport layer on the light-emitting layer, an electron injection layer which is on the electron transport layer and has a thickness, and among the light-emitting areas, the thickness of the electron injection layer in the light-emitting area which emits the red light being greater than the thickness of the electron injection layer in the light-emitting area which emits the green light and being greater than the thickness of the electron injection layer in the light-emitting area which emits the blue light.

The foregoing is illustrative of embodiments and is not to be construed as limiting thereof. Although a few embodiments have been described, those skilled in the art will readily appreciate that many modifications are possible in the embodiments without materially departing from the novel teachings and advantages of the present inventive concept. Accordingly, all such modifications are intended to be included within the scope of the present inventive concept as defined in the claims. Therefore, it is to be understood that the foregoing is illustrative of various embodiments and is not to be construed as limited to the specific embodiments disclosed, and that modifications to the disclosed embodiments, as well as other embodiments, are intended to be included within the scope of the appended claims.

What is claimed is:

1. A display device comprising:
light-emitting areas including a first light-emitting area, a second light-emitting area and a third light-emitting area, and a non-light emitting area which is between the light-emitting areas;
a hole transport layer in each of the light-emitting areas;
light-emitting layers on the hole transport layer, the light-emitting layers including:
a first light-emitting layer which is in the first light-emitting area and emits light of a first color;
a second light-emitting layer which is in the second light-emitting area and emits light of a second color different from the first color; and
a third light-emitting layer which is in the third light-emitting area and emits light of a third color different from the first color and the second color;
an electron transport layer on each of the light-emitting layers; and
electron injection layers which are on the electron transport layer, the electron injection layers including:
a first electron injection layer which is in the first light-emitting area, faces the first light-emitting layer and has a first thickness;
a second electron injection layer which is in the second light-emitting area, faces the second light-emitting layer and has a second thickness; and
a third electron injection layer which is in the third light-emitting area, faces the third light-emitting layer and has a third thickness,
wherein
the first color is red, the second color is green and the third color is blue, and
among the electron injection layers, the first thickness of the first electron injection layer which is in the first light-emitting area is greater than each of the second thickness and the third thickness.

2. The display device of claim 1, wherein the second thickness is equal to the third thickness.

3. The display device of claim 1, wherein the first electron injection layer, the second electron injection layer and the third electron injection layer are spaced apart from each other along the electron transport layer.

4. The display device of claim 1, wherein the first electron injection layer, the second electron injection layer and the third electron injection layer include a lanthanum metal material.

5. The display device of claim 1, wherein the first electron injection layer, the second electron injection layer and the third electron injection layer include ytterbium.

6. The display device of claim 1, wherein the first electron injection layer, the second electron injection layer and the third electron injection layer include both a metal halide material and a lanthanum metal material.

7. The display device of claim 6, wherein the lanthanum metal material includes ytterbium.

8. The display device of claim 1, wherein each of the first thickness, the second thickness and the third thicknesses is about 7.5 angstroms to about 18.5 angstroms.

9. The display device of claim 1, wherein the electron transport layer is continuously disposed as a common layer in the first light-emitting area, the second light-emitting area, the third light-emitting area and the non-light emitting area.

10. The display device of claim 1, wherein the hole transport layer includes:
a hole injection sub-layer; and
a hole transport sub-layer on the hole injection sub-layer.

11. The display device of claim 10, wherein the hole transport layer is continuously disposed as a common layer in the first light-emitting area, the second light-emitting area, the third light-emitting area and the non-light emitting area.

12. The display device of claim 1, further comprising:
an encapsulation layer on the electron injection layers, the encapsulation layer including at least one organic layer and at least one inorganic layer;
a light blocking layer which is on the encapsulation layer and overlaps the non-light emitting area; and
a color filter layer which is on the light blocking layer, the color filter layer including a first color filter, a second color filter and a third color filter respectively in the first light-emitting area, the second light-emitting area and the third light-emitting area.

13. The display device of claim 12, further comprising:
an overcoat layer on the first color filter, the second color filter and the third color filter.

14. The display device of claim 1, further comprising:
an encapsulation layer on the electron injection layers, the encapsulation layer including at least one organic layer and at least one inorganic layer;
a light blocking layer which is on the encapsulation layer and overlaps the non-light emitting area; and
a reflection control layer on the light blocking layer, the reflection control layer including:
an inorganic material containing dye, pigment or a combination thereof, or
an organic material containing dye, pigment or a combination thereof.

15. A display device comprising:
light-emitting areas including a first light-emitting area, a second light-emitting area and a third light-emitting area, and a non-light emitting area which is between the light-emitting areas;
a hole transport layer in each of the light-emitting areas;
light-emitting layers on the hole transport layer, the light-emitting layers including:
a first light-emitting layer which is in the first light-emitting area and includes a light-emitting material which emits red light;
a second light-emitting layer which is in the second light-emitting area and includes a light-emitting material which emits green light; and
a third light-emitting layer which is in the third light-emitting area and includes a light-emitting material which emits blue light;
an electron transport layer on each of the light-emitting layers;
electron injection layers which are on the electron transport layer, the electron injection layers including:
a first electron injection layer which is in the first light-emitting area and faces the first light-emitting layer;
a second electron injection layer which is in the second light-emitting area and faces the second light-emitting layer; and
a third electron injection layer which is in the third light-emitting area and faces the third light-emitting layer;
a light blocking layer which is on the electron injection layers and defines a first opening, a second opening and a third opening respectively overlapping the first light-emitting area, the second light-emitting area and the third light-emitting area; and
a first color filter, a second color filter and a third color filter respectively filling the first opening, the second opening and the third opening,
wherein among the electron injection layers:
the first electron injection layer, the second electron injection layer and the third electron injection layer have a first thickness, a second thickness and a third thickness, respectively, and
the first thickness of the first electron injection layer facing the first light-emitting layer which emits the red light is greater than each of the second thickness and the third thickness.

16. The display device of claim 15, wherein the first electron injection layer, the second electron injection layer and the third electron injection layer are spaced apart from each other.

17. The display device of claim 15, wherein the first electron injection layer, the second electron injection layer and the third electron injection layer include a lanthanum metal material.

18. The display device of claim 15, wherein the first electron injection layer, the second electron injection layer and the third electron injection layer include ytterbium.

19. The display device of claim 15, wherein each of the first thickness, the second thickness and the third thickness is about 7.5 angstroms to about 18.5 angstroms.

20. An electronic device comprising:
a display device including a display area; and
a processor which controls the display device,
wherein the display device includes in the display area:
light-emitting areas respectively emitting red light, green light and blue light;
a non-light emitting area which is between the light-emitting areas; and
in each of the light-emitting areas:
a hole transport layer;
a light-emitting layer on the hole transport layer;
an electron transport layer on the light-emitting layer;
an electron injection layer which is on the electron transport layer and has a thickness; and
among the light-emitting areas, the thickness of the electron injection layer in the light-emitting area which emits the red light being greater than the thickness of the electron injection layer in the light-emitting area which emits the green light and being greater than the thickness of the electron injection layer in the light-emitting area which emits the blue light.
